(19) United States
(12) Patent Application Publication
(10) Pub. No.: US 2025/0093222 A1
(43) Pub. Date: Mar. 20, 2025

(54) METAL VAPOUR PRESSURE DETECTION APPARATUS AND DETECTION METHOD

(71) Applicant: Baoshan Iron & Steel Co., Ltd., Shanghai (CN)

(72) Inventors: Xiaoli Jin, Shanghai (CN); Yueming Zhou, Shanghai (CN); Shanqing Li, Shanghai (CN); Chunwei Zhang, Shanghai (CN); Fei Xiong, Shanghai (CN); Yiru Wang, Shanghai (CN)

(21) Appl. No.: 18/727,625

(22) PCT Filed: Jan. 17, 2023
(86) PCT No.: PCT/CN2023/072543

§ 371 Date: Jul. 9, 2024

(30) Foreign Application Priority Data
Jan. 17, 2022 (CN) 202210048695.5

(51) Int. Cl. G01L 11/00; C23C 14/24; G01L 19/14; G01L 27/00

(52) U.S. Cl. CPC G01L 11/004; G01L 19/147; G01L 27/002; C23C 14/24

(57) ABSTRACT

Provided are a metal vapour pressure detection apparatus and detection method. The metal vapour pressure detection apparatus comprises a metal evaporation cavity (1) and a pressure detection mechanism (3) disposed on the outer side the metal evaporation cavity (1). The metal evaporation cavity (1) is used for melting and evaporating metal to form metal vapour. The pressure detection mechanism (3) comprises a displacement generation system and a displacement detection system disposed on the displacement generation system. The displacement generation system comprises a displacement slider sleeve (5), a displacement slider (4) disposed in the displacement slider sleeve (5), and a pressure balance spring (6) connected to the displacement slider (4). In the metal vapour pressure detection apparatus, metal vapour pressure can be directly obtained, providing a basis for online control and adjustment of metal vapour.

### TECHNICAL FIELD

The present invention belongs to the technical field of metal vapour detection, and particularly relates to a metal vapour pressure detection apparatus and detection method.

### BACKGROUND

Physical vapor deposition (PVD) is a widely used material surface treatment technology that evaporates metals, alloys, or compounds in a vacuum environment, causing the formed metal vapour to condense and deposit on a substrate. Coating the surface of a material by using this technology enables a coating to have better wear resistance, corrosion resistance, and dry lubrication, as well as high hardness, which can significantly improve the performance and service life of the material. This technology is environmentally friendly and widely used in the fields of machinery, electronics, hardware, aerospace, chemical industry, etc., making it an important application technology in green manufacturing.

In the application of the physical vapor deposition technology, a variety of coating materials, such as zinc, aluminum, magnesium, and chromium can be used. The coating speed is generally fast, typically up to 1-3 m/s. In order to obtain a better coating surface quality and spraying effect, it is required to maintain a relatively constant metal vapour flow rate and pressure of metal vapour during the spraying process. The pressure of metal vapour is critical for controlling the spraying process and is one of the key parameters that determine the bonding strength between the coating and the substrate.

At present, common pressure detection devices are mainly suitable for gases and water vapour. Since metal vapor is a high-temperature airflow, it easily condenses in low temperature regions, and some metals are relatively reactive and can easily react with other metals to corrode them. Therefore, existing pressure detection devices cannot directly obtain the pressure of metal vapour. At present, there are few reports on metal vapour pressure detection methods, and most of them use indirect methods for pressure measurement.

After literature research and patent searches, there is currently no method or apparatus for directly measuring metal vapour pressure. Therefore, it is necessary to develop a measurement method and apparatus that can directly obtain the metal vapour pressure to provide a basis for online control and adjustment of metal vapour.

### SUMMARY

To address the above deficiencies existing in the prior art, the present invention provides a metal vapour pressure detection apparatus and detection method. By setting up a displacement generation system and a displacement detection system on an outer side of a metal evaporation cavity, and the pressure of metal vapour is directly measured according to a displacement of a displacement slider detected in real time and a relationship curve between a pressure and the displacement obtained by gas calibration, providing a basis for online control and adjustment of metal vapour.

To achieve the above object, the present invention adopts the following technical solutions:

The first aspect of the present invention provides a metal vapour pressure detection apparatus, including a metal evaporation cavity and a pressure detection mechanism disposed on an outer side of the metal evaporation cavity, wherein
the metal evaporation cavity is used to melt and evaporate metal to form metal vapour; and
the pressure detection mechanism includes a displacement generation system and a displacement detection system disposed on the displacement generation system; the displacement generation system includes a displacement slider sleeve, a displacement slider disposed in the displacement slider sleeve, and a pressure balance spring connected to the displacement slider, the displacement slider sleeve is in communication with the metal evaporation cavity, and the displacement slider slides along the displacement slider sleeve under a pressure of the metal vapour; one end of the pressure balance spring is connected to the displacement slider, and the other end is connected to the displacement detection system; and the pressure detection mechanism determines the pressure of the metal vapour according to coordinates of the displacement slider detected by the displacement detection system.

Preferably, the displacement detection system includes a fixed bracket and a displacement sensor; the fixed bracket is provided with a spring limiting block connected to the pressure balance spring, a fixing ring sleeved on the displacement slider sleeve, and a sensor fixing block for mounting the displacement sensor; and the spring limiting block is disposed between the fixing ring and the sensor fixing block, and the spring limiting block is provided with a light-transmitting hole corresponding to the displacement sensor.

Preferably, the displacement generation system further includes a heater disposed in the displacement slider sleeve.

Preferably, the pressure balance spring is composed of 1-10 springs, with a wire diameter of 0.1-6 mm.

Preferably, a center of the displacement sensor, a center of the light-transmitting hole, and a center of the pressure balance spring are on the same axis.

Preferably, the pressure detection mechanism further includes an intelligent processing module; and the intelligent processing module is used to receive the coordinates of the displacement slider detected by the displacement sensor, calculate a displacement of the displacement slider, and obtain the pressure of the metal vapour according to the displacement of the displacement slider and a relationship curve between the displacement and a pressure obtained by calibration.

The second aspect of the present invention provides a metal vapour pressure detection method, using the metal vapour pressure detection apparatus described above. The detection method includes the steps of:

S1, introducing gas with different pressures into a metal evaporation cavity of the metal vapour pressure detection apparatus for repeated calibration to obtain a relationship curve between a pressure and a displacement of a displacement slider;

S2, melting and evaporating metal to form metal vapour in the metal evaporation cavity, wherein the displacement slider slides along a displacement slider sleeve under a pressure of the metal vapour, and a pressure balance spring gradually contracts under extrusion of the displacement slider until the displacement slider reaches a force equilibrium and stops moving, and a displacement detection system detects coordinates of the displacement slider in real time to obtain a displacement of the displacement slider; and

S3, obtaining the pressure of the metal vapour according to the relationship curve between the pressure and the displacement of the displacement slider obtained in the step S1 and the displacement of the displacement slider obtained in the step S2.

Preferably, in the step S1, the gas has a pressure of 1×10³-1×10⁵ Pa.

Preferably, in the step S2, the displacement ΔS of the displacement slider is:

$$Δ S = \vert {S}_{t} - {S}_{0} \vert$$

wherein ΔS is the displacement of the displacement slider, in mm;
Sₜ represents coordinates of the displacement slider when it reaches a force equilibrium after moving, in mm; and
S₀ represents coordinates of the displacement slider at a zero position (the initial coordinate of the displacement slider), in mm.

Preferably, in the step S2, the displacement slider sleeve is heated by a heater to a temperature of 20-1000° C. during movement of the displacement slider.

The metal vapour pressure detection apparatus and detection method provided by the present invention have the following beneficial effects:
1. The metal vapour pressure detection apparatus and detection method of the present invention, through the displacement generation system and the displacement detection system disposed on the outer side of the metal evaporation cavity, directly measure the pressure of the metal vapour based on the displacement of the displacement slider detected in real time and the relationship curve between the pressure and the displacement obtained by gas calibration, thereby providing a basis for online control and adjustment of metal vapour.
2. The metal vapour pressure detection apparatus and detection method of the present invention can monitor the metal vapour pressure in a temperature range from normal temperature to 1000° C. in real time, providing a stable detection and adjustment basis for metal evaporation control.
3. The metal vapour pressure detection apparatus and detection method of the present invention are suitable for directly obtaining pressures of various metal vapours, featuring good structural adaptability and process compatibility.
4. The metal vapour pressure detection apparatus of the present invention is simple in structure, suitable for various operating conditions and environments, cost-effective, easy to operate and maintain, and facilitates automatic interlocking control.

### BRIEF DESCRIPTION OF THE DRAWINGS

FIG. 1 is a structural schematic diagram of a metal vapour pressure detection apparatus according to the present invention.

FIG. 2a is a structural schematic diagram of a pressure detection mechanism according to the present invention.

FIG. 2b is a sectional view taken along line A-A of FIG. 2a.

FIG. 3a is a schematic diagram showing a displacement slider of the pressure detection mechanism of the present invention under the action of metal vapour pressure.

FIG. 3b is a sectional view taken along line B-B of FIG. 3a.

FIG. 4 is a structural schematic diagram of a fixed bracket according to the present invention.

FIG. 5a is a structural schematic diagram of a displacement slider sleeve according to the present invention.

FIG. 5b is a sectional view taken along line C-C of FIG. 5a.

FIG. 6 is a structural schematic diagram of a pressure balance spring composed of multiple springs having different specifications, such as wire diameters.

### REFERENCE SIGNS

1—metal evaporation cavity, 2—metal evaporation area, 3—pressure detection mechanism, 4—displacement slider, 5—displacement slider sleeve, 6—pressure balance spring, 7-fixed bracket (7-1 spring limiting block; 7-2 sensor fixing block; 7-3 fixing ring), 8—displacement sensor, and 9—heater.

### DETAILED DESCRIPTION

In order to better understand the above technical solutions of the present invention, the technical solutions of the present invention are further illustrated below in conjunction with the following embodiments.

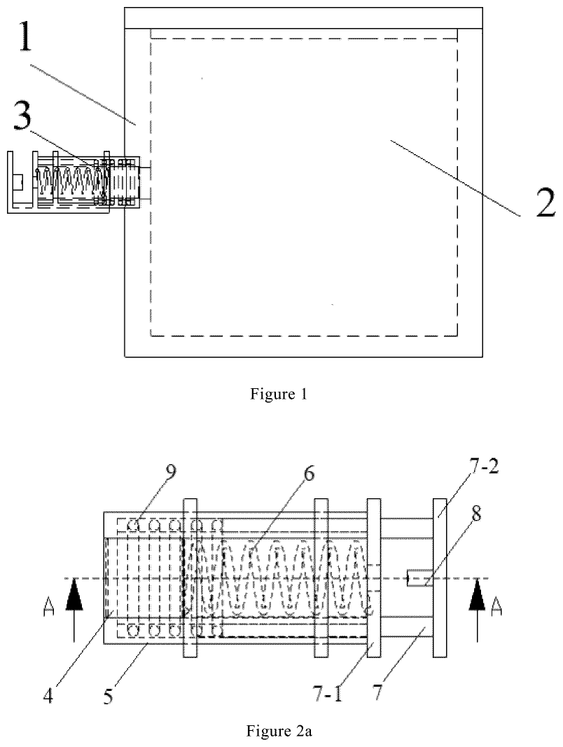

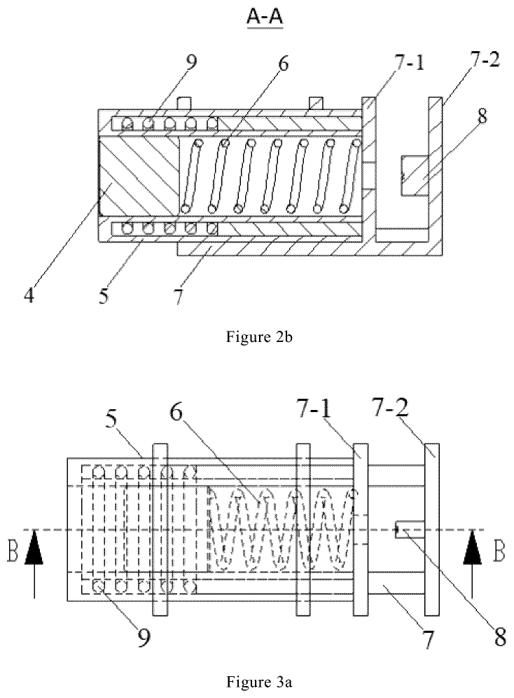

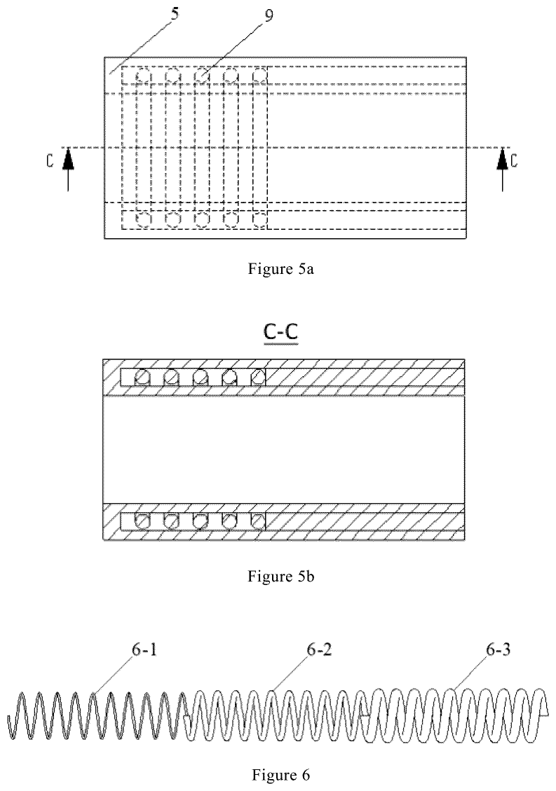

As shown in FIG. 1, the present invention provides a metal vapour pressure detection apparatus, including a metal evaporation cavity 1 and a pressure detection mechanism 3 disposed on an outer side of the metal evaporation cavity 1. The metal evaporation cavity 1 is used to melt and evaporate metal to form metal vapour, with its interior being a metal evaporation area 2. As shown in FIGS. 2a and 2b, the pressure detection mechanism 3 includes a displacement generation system and a displacement detection system disposed on the displacement generation system. The displacement generation system includes a displacement slider sleeve 5 (as shown in FIGS. 5a and 5b), a displacement slider 4 disposed in the displacement slider sleeve 5, and a pressure balance spring 6 connected to the displacement slider 4. The displacement slider sleeve 5 is in communication with the metal evaporation cavity 1, and the displacement slider 4 slides radially along the displacement slider sleeve 5 under a pressure of the metal vapour. One end (movable end) of the pressure balance spring 6 is connected to the displacement slider 4, and the other end (fixed end) of the pressure balance spring 6 is connected to the displacement detection system. The pressure detection mechanism 3 calculates a displacement of the displacement slider 4 based on the coordinates of the displacement slider 4 detected by the displacement detection system, and thereby determines the pressure of metal vapour.

As shown in FIGS. 2a and 2b, the displacement detection system of the present invention further includes a fixed bracket 7 and a displacement sensor 8. As shown in FIG. 4, the fixed bracket 7 is provided with a spring limiting block 7-1 connected to the pressure balance spring 6, a fixing ring 7-3 sleeved on the displacement slider sleeve 5, and a sensor fixing block 7-2 for mounting the displacement sensor 8. Two fixing rings 7-3 are arranged in order to make the fixed bracket more stable. The spring limiting block 7-1 is disposed between the fixing ring 7-3 and the sensor fixing block 7-2, and is provided with a light-transmitting hole corresponding to the displacement sensor 8. The fixed bracket 7 serves three functions: firstly, the position of the fixed end is defined by the spring limiting block 7-1 when the pressure balance spring 6 is deformed, and the light-transmitting hole corresponding to the displacement sensor 8 is designed in the spring limiting block 7-1, facilitating the displacement sensor 8 to perform real-time measurement on the coordinates of the displacement slider 4; secondly, the displacement sensor 8 is mounted on the sensor fixing block 7-2, which can measure the displacement of the displacement slider 4 under the action of metal vapour; and thirdly, the fixed bracket 7 is mounted on the displacement slider sleeve 5 through the fixing rings 7-3, making the fixed bracket 7 an important component connecting the displacement generation system and the displacement detection system.

In the present invention, a center of the displacement sensor 8, a center of the pressure balance spring 6, and a center of the light-transmitting hole are essentially on the same axis to ensure that the displacement sensor 8 is not obstructed by other components during the measurement.

As shown in FIGS. 2a and 2b, in order to prevent the metal vapour from condensing between the displacement slider 4 and the displacement slider sleeve 5, and on an inner wall of the displacement slider sleeve 5, which affects the metal vapour pressure detection effect, the displacement generation system further includes a heater 9 disposed within the displacement slider sleeve 5, which can heat the displacement slider sleeve 5 to a temperature above the metal vapour temperature. In the present invention, the heater 9 employs resistance heating or induction heating, with a heating temperature range of 20-1000° C.

As shown in FIG. 6, in practical applications, a reasonable pressure balance spring 6 may be designed according to different pressure ranges. For example, when a metal vapour pressure detection range is 1×10³-10⁵ Pa, the pressure balance spring 6 may be composed of a single spring or multiple springs, thereby enabling a wide range of metal vapour pressure measurements. For example, in the present invention, the pressure balance spring 6 is composed of 1-10 springs. When the metal vapour pressure is measured by using a combination of multiple springs, the multiple springs are connected in series to form the pressure balance spring 6. For example, in FIG. 6, three springs with different wire diameters (6-1, 6-2, and 6-3) are connected in series to form the pressure balance spring 6. In the pressure balance spring 6, a wire diameter of each spring can be designed according to a pressure range to be measured, with a selectable wire diameter between 0.1 mm and 6 mm.

In the present invention, the pressure detection mechanism 3 further includes an intelligent processing module. In the metal evaporation process, the intelligent processing module receives the coordinates of the displacement slider 4 measured in real time by the displacement sensor 8, calculates a displacement ΔS of the displacement slider 4, and obtains the pressure of the metal vapour according to the displacement ΔS and a relationship curve between a pressure and the displacement ΔS of the displacement slider 4 obtained by calibration, thereby obtaining the pressure of the metal vapour in real time.

The metal vapour pressure detection apparatus of the present invention can be used for measuring metal vapour pressure under both normal and vacuum conditions, making it suitable for measuring metal vapour pressure under various operating conditions. The metal vapour pressure detection apparatus of the present invention can directly obtain the pressure of the metal vapour, with minimal influence from other factors, and has a high anti-interference ability, and relatively stable pressure measurement.

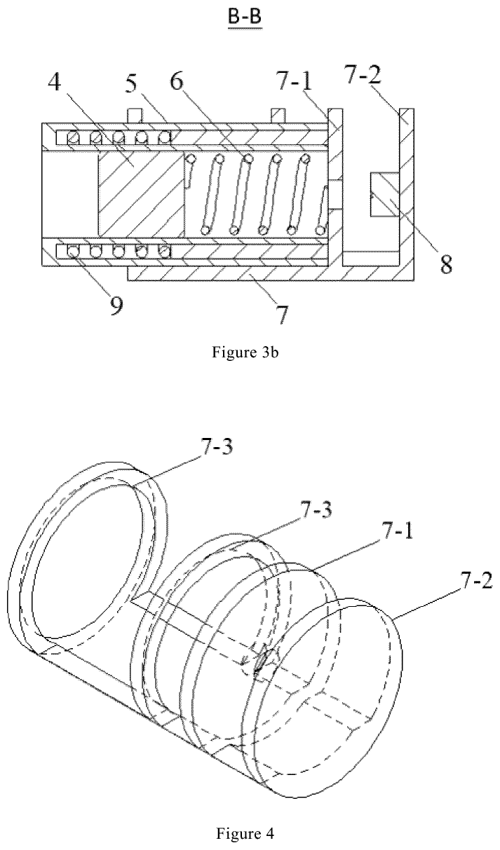

When the metal vapour pressure detection apparatus of the present invention is in use, in the absence of metal vapour, the displacement slider 4 rests against the metal evaporation cavity 1 (an outer wall of the metal evaporation cavity 1 is provided with a limiting part to keep the displacement slider 4 within the displacement slider sleeve 5) under the compressive stress of the pressure balance spring 6, forming a force equilibrium. This position represents coordinates of the displacement slider 4 when it has not moved, referred to as a zero position S₀. As shown in FIGS. 3a and 3b, when metal vapour is generated (or other gases are introduced) in the metal evaporation cavity 1, as the evaporation process proceeds, the metal vapour pressure in the metal evaporation cavity 1 increases. When the metal vapour pressure exceeds the initial compressive stress of the pressure balance spring 6, the net external force on the displacement slider 4 is directed away from the metal evaporation cavity 1 (outward). The displacement slider 4 moves along a wall of the displacement slider sleeve 5 in a direction away from the metal evaporation cavity 1. The pressure balance spring 6 gradually contracts under extrusion of the displacement slider 4, and at the same time, its compressive stress to the displacement slider 4 gradually increases. When the compressive stress of the pressure balance spring 6 equals the pressure of the metal vapour, the displacement slider 4 reaches a force equilibrium and stops moving. During the metal evaporation process, the pressure of the metal vapour generated inside the metal evaporation cavity 1 decreases, when the pressure of the metal vapour is less than the compressive stress of the pressure balance spring 6, the net external force of the displacement slider 4 is directed towards the metal evaporation cavity 1 (inward). The displacement slider 4 moves towards the metal evaporation cavity 1, and the compressive stress of the pressure balance spring 6 on the displacement slider 4 gradually decreases. When the compressive stress of the pressure balance spring 6 on the displacement slider 4 equals the metal vapour pressure, the displacement slider 4 stops moving. When the metal evaporation is nearing completion and the metal vapour pressure continues to decrease, the displacement slider 4 moves toward the metal evaporation cavity 1 under the internal stress of the pressure balance spring 6 until it rests against the metal evaporation cavity 1, indicating that the metal vapour pressure is lower than the minimum detection pressure of the metal vapour pressure detection apparatus. During the movement of the displacement slider 4 from moving away from the metal evaporation cavity 1 to reaching force equilibrium and stopping, the coordinates of the displacement slider 4 are measured in real time by the displacement sensor 8 and transferred to the intelligent processing module, which can calculate the displacement ΔS of the displacement slider 4 in real time, and then determine the pressure of the metal vapour according to the displacement ΔS and the relationship curve between the pressure and the displacement obtained through gas calibration.

The pressure of the metal vapour is detected by using the metal vapour pressure detection apparatus described above, wherein a detection method includes the following steps:

S1, introduce gas with different pressures into a metal evaporation cavity of the metal vapour pressure detection apparatus for repeated calibration to obtain a relationship curve between a pressure and a displacement of a displacement slider.

The specific process is as follows: before a metal vapour pressure is obtained, a relationship between a pressure of the metal vapour pressure detection apparatus and the displacement of the displacement slider is first calibrated. Gas with a known pressure is introduced into the metal evaporation cavity, the displacement slider moves away from the metal evaporation cavity under the action of the gas, a pressure balance spring gradually contracts under extrusion of the displacement slider while exerting an inward compressive stress to the displacement slider until the displacement slider reaches a force equilibrium and stops moving. The displacement detection system measures coordinates of the displacement slider in real time. When no gas is introduced into the metal evaporation cavity, the displacement slider rests against the limiting part on the outer wall of the metal evaporation cavity under the action of the inward compressive stress of the pressure balance spring, forming a force equilibrium, and at this time, the position of the displacement slider is recorded as the zero position S₀. Based on the above process, obtain the relationship curve between the pressure and the displacement of the displacement slider. In order to ensure the accuracy of data, repeated calibrations are required. Additionally, the pressure of the gas also needs to be increased or decreased to perform multiple repeated calibrations of the relationship between the pressure and the displacement of the displacement slider for a plurality of times to obtain the relationship curve between the pressure and the displacement of the displacement slider. The gas used during calibration has a pressure of 1×10³-1×10⁵ Pa.

S2, melt and evaporate the metal to form metal vapour in the metal evaporation cavity. The displacement slider slides along a displacement slider sleeve under a pressure of the metal vapour. The pressure balance spring gradually contracts under extrusion of the displacement slider until the displacement slider reaches a force equilibrium and stops moving. The displacement detection system detects coordinates of the displacement slider in real time to obtain a displacement of the displacement slider.

The specific process is as follows: melt and evaporate the metal to form the metal vapour in the metal evaporation cavity. When the pressure of the metal vapour exceeds an initial internal stress of the pressure balance spring, the displacement slider slides along the displacement slider sleeve under the pressure of the metal vapour. The pressure balance spring gradually contracts under the extrusion of the displacement slider. When the internal stress of the pressure balance spring to the displacement slider equals the pressure of the metal vapour, the displacement slider stops moving. The displacement detection system detects coordinates Sₜ of the displacement slider at this time in real time and sends them to a pressure detection system to obtain the displacement ΔS of the displacement slider:

$$Δ S = \vert {S}_{t} - {S}_{0} \vert$$

wherein ΔS is the displacement of the displacement slider, in mm;
Sₜ represents coordinates of the displacement slider when it reaches a force equilibrium and stops moving after moving, in mm; and
S₀ represents coordinates of the displacement slider at a zero position, in mm.

When the pressure of the metal vapour changes, the displacement at this time can be recalculated based on the coordinates detected by the displacement detection system after the displacement slider reaches a force equilibrium again.

In the above process, in order to prevent the metal vapour from condensing between the displacement slider and the displacement slider sleeve and on the inner wall of the displacement slider sleeve, which would affect the metal vapour pressure detection effect, the displacement slider sleeve is heated by a heater to a temperature of 20-1000° C.

S3, obtain the pressure of the metal vapour according to the relationship curve between the pressure and the displacement of the displacement slider obtained in the step S1 and the displacement obtained in the step S2.

The specific process is as follows: the pressure of the metal vapour is obtained in real time according to the relationship curve between the pressure and the displacement of the displacement slider obtained in the step S1 and the displacement detected in the step S2.

The metal vapour pressure detection apparatus and detection method of the present invention are further described below with reference to specific examples.

### EXAMPLE 1

In this example, the metal vapour pressure to be measured is in the range of 5×10³-1×10⁵ Pa, and the pressure balance spring 4 is composed of a single spring with a wire diameter of 4-6 mm. The implementation steps are as follows:

First, the metal vapour pressure detection apparatus is calibrated as follows:

In an initial state, the displacement sensor 8 records coordinates S₀ of an initial zero position of the displacement slider 4 and sends them to the intelligent processing module.

Introduce nitrogen gas into the metal evaporation cavity 1. As the pressure of the nitrogen gas in the metal evaporation cavity 1 increases, the displacement slider 4 moves outward under the net external force. The pressure of the nitrogen gas in the cavity can be measured by a pressure gauge, and the displacement sensor 8 can detect the displacement of the displacement slider 4 in real time to obtain a relationship between the displacement and the pressure during the increase of the gas pressure.

When the pressure of the nitrogen gas in the metal evaporation cavity reaches 1×10⁵ Pa, gradually reduce the pressure of the nitrogen in the metal evaporation cavity to 5×10³ Pa. During this process, as the pressure of the gas acting on the displacement slider 4 decreases, the net external force becomes inward. Measure the real-time displacement of the displacement slider 4 to obtain a relationship between the displacement and the pressure during the decrease of the gas pressure.

Throughout the calibration process, the displacement of the displacement slider 4 and a corresponding value of the gas pressure in the metal evaporation cavity are sent to the intelligent processing module in real time. By repeating the measurement for a plurality of times, a relationship curve between the displacement and the pressure is obtained.

Then, the metal vapour pressure in the metal evaporation cavity is obtained by using the relationship curve between the displacement and the pressure from the above calibration.

Record the initial zero position of the displacement slider in an initial state of metal melting and evaporation and send it to the intelligent processing module.

Heat the metal in the metal evaporation cavity 1 to achieve melting and evaporation and measure the temperature of a metal melting and evaporation area in real time, send it to the intelligent processing module.

The intelligent processing module sends the real-time temperature inside the metal evaporation cavity 1 to the heater 9, which heats the displacement slider sleeve 5 to a target temperature (greater than or equal to the metal vapour temperature) to avoid condensation of the metal vapour on the pressure detection apparatus.

The displacement sensor 8 detects the displacement generated by the displacement slider 4 in real time. The real time pressure of the metal vapour in the metal evaporation cavity 1 is determined using the relationship curve between the displacement and pressure obtained from the calibration.

Using the above method, stable measurement of the metal vapour pressure in a range of 5×10³-1×10⁵ Pa can be achieved.

### EXAMPLE 2

In this example, the metal vapour pressure to be measured is in the range of 1×10³-5×10³ Pa, and the pressure balance spring 4 is composed of a single spring with a wire diameter of 2-5 mm. The specific implementation method and steps are the same as those in Example 1.

### EXAMPLE 3

In this example, the metal vapour pressure to be measured is in the range of 1×10³-5×10³ Pa, and the pressure balance spring 4 is composed of two or more springs with different wire diameters in series, with wire diameters of 0.1-5 mm. This allows for high-precision metal vapour pressure detection.

In summary, in the present invention, the displacement generation system and the displacement detection system are disposed on the outer side of the metal evaporation cavity, and the pressure of metal vapour is directly obtained according to the displacement of the displacement slider detected in real time and the relationship curve between the pressure and the displacement obtained by gas calibration, providing a basis for online control and adjustment of metal vapour. The metal vapour pressure detection apparatus and detection method of the present invention can monitor the metal vapour pressure in a temperature range from normal temperature to 1000° C. in real time, providing a stable detection and adjustment basis for metal evaporation control. The metal vapour pressure detection apparatus and detection method of the present invention are suitable for detecting pressures of various metal vapours, with good structural flexibility and process compatibility. The metal vapour pressure detection apparatus of the present invention is simple in structure, suitable for various operating conditions and environments, and particularly suitable for metal vapour pressure detection under vacuum conditions. It is cost-effective, easy to operate and maintain, and facilitates automatic interlocking control.

It will be appreciated by those skilled in the art that the above examples are merely illustrative of the present invention and are not intended to limit it. Any changes and variations of the above examples within the spirit of the present invention are intended to be covered by the claims of the present invention.

1. A metal vapour pressure detection apparatus, wherein the detection apparatus comprises a metal evaporation cavity and a pressure detection mechanism disposed on an outer side of the metal evaporation cavity, wherein
the metal evaporation cavity is used to melt and evaporate metal to form metal vapour; and
the pressure detection mechanism comprises a displacement generation system and a displacement detection system disposed on the displacement generation system; the displacement generation system comprises a displacement slider sleeve, a displacement slider disposed in the displacement slider sleeve, and a pressure balance spring connected to the displacement slider; the displacement slider sleeve is in communication with the metal evaporation cavity, and the displacement slider slides along the displacement slider sleeve under a pressure of the metal vapour; one end of the pressure balance spring is connected to the displacement slider, and the other end is connected to the displacement detection system; and the pressure detection mechanism determines the pressure of the metal vapour according to coordinates of the displacement slider detected by the displacement detection system.

2. The metal vapour pressure detection apparatus according to claim 1, wherein the displacement detection system further comprises a fixed bracket and a displacement sensor; the fixed bracket is provided with a spring limiting block connected to the pressure balance spring, a fixing ring sleeved on the displacement slider sleeve, and a sensor fixing block for mounting the displacement sensor; and the spring limiting block is disposed between the fixing ring and the sensor fixing block, and the spring limiting block is provided with a light-transmitting hole corresponding to the displacement sensor.

3. The metal vapor pressure detection apparatus according to claim 1, wherein the displacement generation system further comprises a heater disposed in the displacement slider sleeve.

4. The metal vapour pressure detection apparatus according to claim 1, wherein the pressure balance spring is composed of 1-10 springs, with a wire diameter of 0.1-6 mm.

5. The metal vapour pressure detection apparatus according to claim 2, wherein a center of the displacement sensor, a center of the light-transmitting hole, and a center of the pressure balance spring are on the same axis.

6. The metal vapour pressure detection apparatus according to claim 1, wherein the pressure detection mechanism further comprises an intelligent processing module; and the intelligent processing module is used to receive the coordinates of the displacement slider detected by the displacement sensor, calculate a displacement of the displacement slider, and obtain the pressure of the metal vapour according to the displacement of the displacement slider and a relationship curve between the displacement and a pressure obtained by calibration.

7. A metal vapour pressure detection method, wherein the metal vapour pressure detection apparatus according to claim 1 is used to detect a metal vapour pressure, wherein the detection method comprises the steps of:
S1, introducing gas with different pressures into a metal evaporation cavity of the metal vapour pressure detection apparatus for repeated calibration to obtain a relationship curve between a pressure and a displacement of a displacement slider;
S2, melting and evaporating metal to form metal vapour in the metal evaporation cavity, wherein the displacement slider slides along a displacement slider sleeve under a pressure of the metal vapour, and a pressure balance spring gradually contracts under extrusion of the displacement slider until the displacement slider reaches a force equilibrium and stops moving, and a displacement detection system detects coordinates of the displacement slider in real time to obtain a displacement of the displacement slider; and
S3, obtaining the pressure of the metal vapour according to the relationship curve between the pressure and the displacement of the displacement slider obtained in the step S1 and the displacement of the displacement slider obtained in the step S2.

8. The metal vapour pressure detection method according to claim 7, wherein in the step S1, the gas has a pressure of 1×10³-1×10⁵ Pa.

9. The metal vapour pressure detection method according to claim 7, wherein in the step S2, the displacement ΔS of the displacement slider is:
$$Δ S = \vert {S}_{t} - {S}_{0} \vert$$
wherein ΔS is the displacement of the displacement slider, in mm;
Sₜ represents coordinates of the displacement slider when it reaches a force equilibrium after moving, in mm; and
S₀ represents coordinates of the displacement slider at a zero position, in mm.

10. The metal vapour pressure detection method according to claim 7, wherein in the step S2, the displacement slider sleeve is heated by a heater to a temperature of 20-1000° C. during movement of the displacement slider.
